(19) United States
(12) Patent Application Publication
(10) Pub. No.: US 2025/0344331 A1
(43) Pub. Date: Nov. 6, 2025

(54) TERMINAL BLOCK FOR MOUNTING DC LINK CAPACITOR

(71) Applicant: Rivian IP Holdings, LLC, Irvine, CA (US)

(72) Inventors: Che Daniel SILKISS-HERO, Long Beach, CA (US); Juan LOPEZ, Wildomar, CA (US); Navin PILLAI, Carson, CA (US); Young DOO, La Palma, CA (US)

(21) Appl. No.: 18/653,134

(22) Filed: May 2, 2024

(51) Int. Cl. H05K 7/14; B60L 15/00; B60L 50/51

(52) U.S. Cl. CPC H05K 7/1428; B60L 15/007; B60L 50/51; H05K 7/14322; H05K 7/14339; B60L 2210/42

(57) ABSTRACT

A capacitor assembly includes a traction inverter system housing and a set of power electronics defining two or more contacts, the set of power electronics mounted within the traction inverter system housing. A capacitor housing containing a capacitor is mounted within the traction inverter system housing. The capacitor includes two or more terminals extending outwardly therefrom and overlapping the two or more contacts. A terminal block is secured to the capacitor housing independent of attachment of the two or more contacts to the two or more terminals. The terminal block is configured to support the two or more terminals during a fastening operation attaching the two or more terminals to the two or more contacts. The terminal block may also be secured to the capacitor housing.

### INTRODUCTION

The present disclosure relates to a terminal block for mounting a power electronics component, such as a DC link capacitor.

### SUMMARY

The present disclosure describes an approach for implementing a terminal block for supporting terminals of a power electronics component, such as a DC link capacitor, during assembly. In one aspect, an assembly includes a traction inverter system housing and a set of power electronics defining two or more contacts, the set of power electronics mounted within the traction inverter system housing. A capacitor housing containing a capacitor is mounted within the traction inverter system housing. The capacitor includes two or more terminals extending outwardly therefrom and overlapping the two or more contacts. A terminal block is secured to the capacitor housing independent of attachment of the two or more contacts to the two or more terminals. The terminal block is configured to support the two or more terminals during a fastening operation attaching the two or more terminals to the two or more contacts.

### BRIEF DESCRIPTION OF THE DRAWINGS

FIG. 1A illustrates an example vehicle that may be operated in accordance with certain embodiments.

FIG. 1B illustrates a chassis of a vehicle having multiple drive units that may be operated in accordance with certain embodiments.

FIG. 2 is a schematic block diagram of components for operating the vehicle in accordance with certain embodiments.

FIG. 3 is schematic block diagram illustrating power electronics of a vehicle in accordance with certain embodiments.

FIGS. 4A and 4B are isometric views of a traction inverter system housing containing power electronics and a DC link capacitor in accordance with certain embodiments.

FIG. 5A is an exploded view of a DC link capacitor in accordance with certain embodiments.

FIG. 5B is an assembled view of the DC link capacitor in accordance with certain embodiments.

FIGS. 6A and 6B are isometric views of a terminal block for supporting terminals in accordance with certain embodiments.

FIG. 7 is an isometric view of terminal blocks in a lower housing for containing the DC link capacitor and power electronics in accordance with certain embodiments.

FIG. 8 is a side view of a terminal block supporting terminals of a DC link capacitor and contacts of power electronics in accordance with certain embodiments.

FIG. 9A is an isometric view of a DC link capacitor housing with an integrated terminal support in accordance with certain embodiments.

FIG. 9B is a partial isometric view of a DC link capacitor housing with an integrated terminal support in accordance with certain embodiments.

### DETAILED DESCRIPTION

A terminal block supports output terminals of a DC link capacitor and contacts of power electronics as the output terminals and contacts are secured to one another by welds, fasteners, or other securement approach. The terminal block includes a retention feature and an alignment feature that retain the terminal block in a traction inverter system housing without the use of fastening tools or additional fasteners. A terminal block may also be secured directly to a housing of the DC link capacitor.

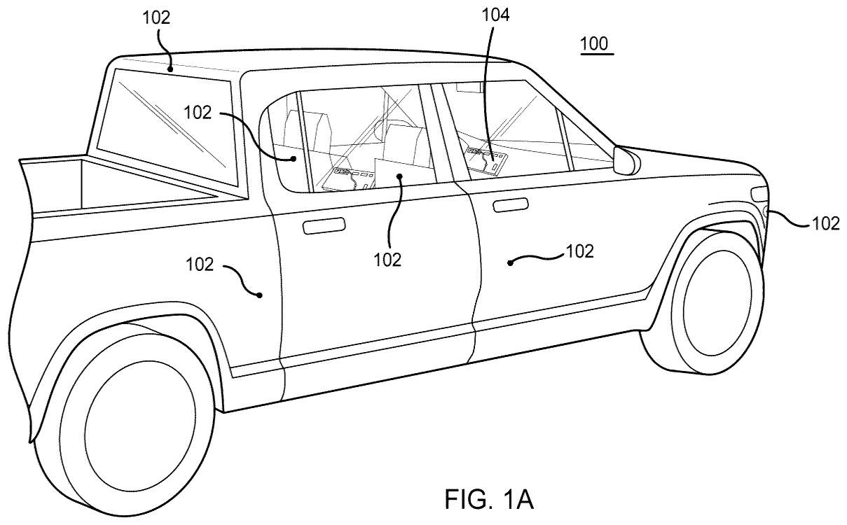

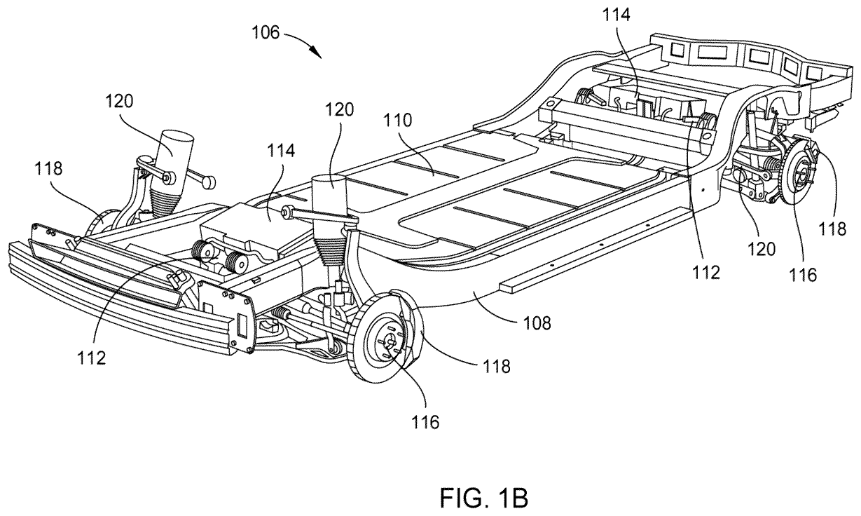

FIG. 1A illustrates an example vehicle 100 in which the approach described herein may be implemented. As seen in FIG. 1A, the vehicle 100 has multiple exterior cameras 102 and one or more front displays 104. Each of these exterior cameras 102 may capture a particular view or perspective on the outside of the vehicle 100. The images or videos captured by the exterior cameras 102 may then be presented on one or more displays in the vehicle 100, such as the one or more front displays 104, for viewing by a driver.

Referring to FIG. 1B, the vehicle 100 may include a chassis 106 including a frame 108 providing a primary structural member of the vehicle 100. The frame 108 may be formed of one or more beams or other structural members or may be integrated with the body of the vehicle (e.g., unibody construction).

In embodiments where the vehicle 100 is a battery electric vehicle (BEV) or possibly a hybrid vehicle, a large battery 110 is mounted to the chassis 106 and may occupy a substantial (e.g., at least 80 percent) of an area within the frame 108. For example, the battery 110 may store from 100 to 200 kilowatt hours (kWh). The battery 110 may be a lithium-ion battery or other type of rechargeable battery. The battery may be substantially planar in shape.

Power from the battery 110 may be supplied to one or more drive units 112. Each drive unit 112 may be formed of an electric motor and possibly a gear train providing a gear reduction. In some embodiments, there is a single drive unit 112 driving either the front wheels or the rear wheels of the vehicle 100. In another embodiment, there are two drive units 112, each driving either the front wheels or the rear wheels of the vehicle 100. In yet another embodiment, there are four drive units 112, each drive unit 112 driving one of four wheels of the vehicle 100.

Power from the battery 110 may be supplied to the drive units 112 by one or more traction inverter systems 114, such as a traction inverter system 114 for each drive unit 112 or pair of drive units 112. The traction inverter systems 114 may include inverters configured to convert direct current (DC) from the battery 110 into alternating current (AC) supplied to the motors of the drive units 112. The traction inverter systems 114 further facilitate operation of the motors of the drive units as generators to provide regenerative braking. The traction inverter systems 114 further facilitate the transfer of regenerative current to the battery 110.

The drive units 112 are coupled to two or more hubs 116 to which wheels may mount. Each hub 116 includes a corresponding brake 118, such as the illustrated disc brakes. Each hub 116 is further coupled to the frame 108 by a suspension 120. The suspension 120 may include metal or pneumatic springs for absorbing impacts. The suspension 120 may be implemented as a pneumatic or hydraulic suspension capable of adjusting a ride height of the chassis 106 relative to a support surface. The suspension 120 may include a damper with the properties of the damper being either fixed or adjustable electronically.

In the embodiment of FIG. 1B and in the discussion below, the vehicle 100 is a battery electric vehicle. However, a hybrid-electric vehicle may also benefit from the approach described herein. Likewise, non-vehicular applications that use an inverter or other relevant power component may also benefit from the approach described herein.

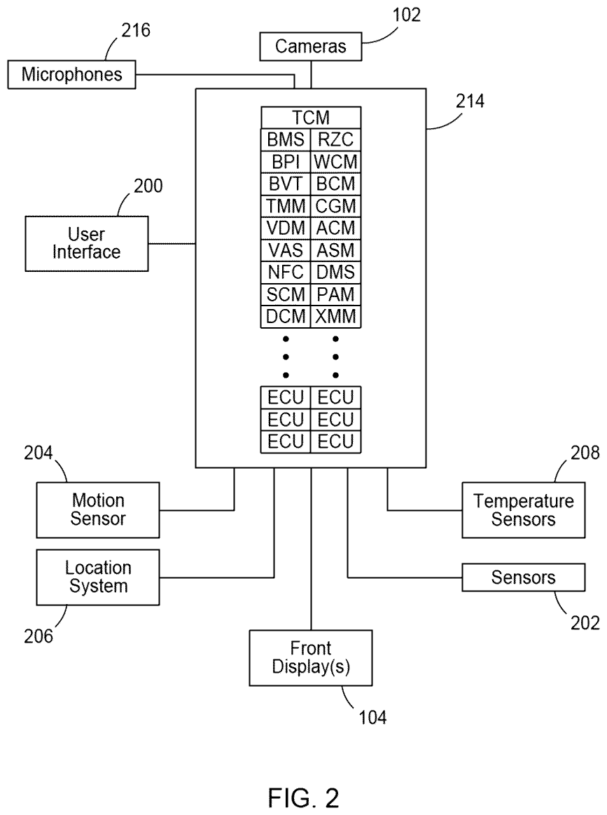

FIG. 2 illustrates example components of the vehicle 100 of FIG. 1A. As seen in FIG. 2, the vehicle 100 includes the cameras 102, the one or more front displays 104, a user interface 200, one or more sensors 202, a motion sensor 204, and a location system 206. The one or more sensors 202 may include ultrasonic sensors, radio detection and ranging (RADAR) sensors, light detection and ranging (LIDAR) sensors, or other types of sensors. The location system 206 may be implemented as a global positioning system (GPS) receiver. The user interface 200 allows a user, such as a driver or passenger in the vehicle 100, to provide input.

The components of the vehicle 100 may include one or more temperature sensors 208. The temperature sensors 208 may include sensors configured to sense an ambient air temperature, temperature of the battery 110, temperature of traction inverter systems 114, temperature of each drive unit 112 and/or each motor of each drive unit 112, temperature of coolant fluid entering or leaving a coolant system, temperature of oil within a drive unit 112, or the temperature of any other component of the vehicle 100. The temperature sensors 208 may include a temperature sensor directly mounted to a microprocessor of the traction inverter systems 114.

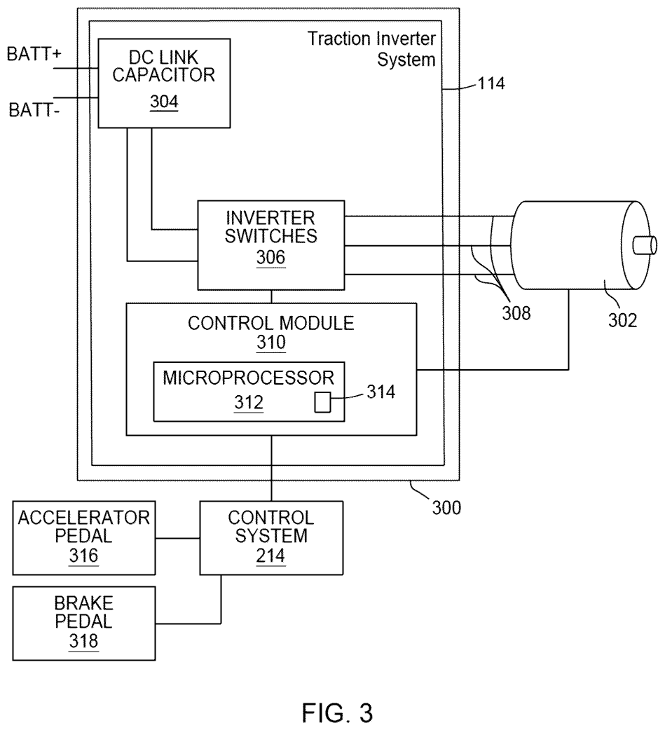

A control system 214 executes instructions to perform at least some of the actions or functions of the vehicle 100. For example, as shown in FIG. 2, the control system 214 may include one or more electronic control units (ECUs) configured to perform at least some of the actions or functions of the vehicle 100, including the functions described in relation to FIGS. 3 to 6. In certain embodiments, each of the ECUs is dedicated to a specific set of functions.

Certain features of the embodiments described herein may be controlled by a Telematics Control Module (TCM) ECU. The TCM ECU may provide a wireless vehicle communication gateway to support functionality such as, by way of example and not limitation, over-the-air (OTA) software updates, communication between the vehicle and the internet, communication between the vehicle and a computing device, in-vehicle navigation, vehicle-to-vehicle communication, communication between the vehicle and landscape features (e.g., automated toll road sensors, automated toll gates, power dispensers at charging stations), or automated calling functionality.

Certain features of the embodiments described herein may be controlled by a Central Gateway Module (CGM) ECU. The CGM ECU may serve as the vehicle's communications hub that connects and transfer data to and from the various ECUs, sensors, cameras, microphones, motors, displays, and other vehicle components. The CGM ECU may include a network switch that provides connectivity through Controller Area Network (CAN) ports, Local Interconnect Network (LIN) ports, and Ethernet ports. The CGM ECU may also serve as the master control over the different vehicle modes (e.g., road driving mode, parked mode, off-roading mode, tow mode, camping mode), and thereby control certain vehicle components related to placing the vehicle in one of the vehicle modes.

In various embodiments, the CGM ECU collects sensor signals from one or more sensors of vehicle 100. For example, the CGM ECU may collect data from cameras 102, sensors 202, motion sensor 204, location system 206, and temperature sensors 208. The sensor signals collected by the CGM ECU are then communicated to the appropriate ECUs for processing.

The control system 214 may also include one or more additional ECUs, such as, by way of example and not limitation: a Vehicle Dynamics Module (VDM) ECU, an Experience Management Module (XMM) ECU, a Vehicle Access System (VAS) ECU, a Near-Field Communication (NFC) ECU, a Body Control Module (BCM) ECU, a Seat Control Module (SCM) ECU, a Door Control Module (DCM) ECU, a Rear Zone Control (RZC) ECU, an Autonomy Control Module (ACM) ECU, an Autonomous Safety Module (ASM) ECU, a Driver Monitoring System (DMS) ECU, and/or a Winch Control Module (WCM) ECU.

If vehicle 100 is an electric vehicle, one or more ECUs may provide functionality related to the battery pack of the vehicle, such as a Battery Management System (BMS) ECU, a Battery Power Isolation (BPI) ECU, a Balancing Voltage Temperature (BVT) ECU, and/or a Thermal Management Module (TMM) ECU. In various embodiments, the XMM ECU transmits data to the TCM ECU (e.g., via Ethernet, etc.). Additionally or alternatively, the XMM ECU may transmit other data (e.g., sound data from microphones 216, etc.) to the TCM ECU.

Referring to FIG. 3, the traction inverter system 114 may be contained within a housing 300, such as a housing made of aluminum or steel. The traction inverter system 114 may include a plurality of components configured to convert direct current (DC) from the battery 110 into alternating current (AC), such as three-phase AC, supplied to one or more motors 302 of the drive unit 112 including the traction inverter system 114.

The traction inverter system 114 may include a DC link capacitor 304 that receives power from the battery 110 and is coupled to the positive and negative terminals (Batt+, Batt−) of the battery 110. The DC link capacitor 304 functions to smooth current received from the battery 110 as part of the process by which the direct current from the battery 110 is converted to an approximately sinusoidal alternating current. The DC link capacitor 304 may further function to dampen any voltage spikes. The DC link capacitor 304 may be within the housing 300 or external to the housing 300.

The traction inverter system 114may include inverter switches 306 coupled to the outputs of the DC link capacitor 304. The inverter switches 306 may include a plurality of switches that are selectively opened and closed to cause transmission of current to the outputs of the traction inverter system 114 at an appropriate frequency for driving the one or more motors 302. For example, the inverter switches 306 may output three-phase current over lines 308 connecting the inverter 306 to the motor 302. The opening and closing of the inverter switches 306 may be controlled by a control module 310. The control module 310 may include a printed circuit board with various electronic components configured to generate the control signals for the inverter switches 306. In some embodiments, the traction inverter system 114 drives two drive units 112 and include separate printed circuit boards for supplying current to the motors 302 of the separate drive units.

The control module 310 may further include a microprocessor 312 programmed to control operation of the control module 310 and therefore the inverter 306. The microprocessor 312 may be embodied as a silicon chip mounted to the printed circuit board of the control module 310. The microprocessor 312 may include a temperature sensor 314 mounted directly thereto.

The control module 310 may be coupled to the control system 214 and implement instructions from the control system 214 to control current supplied to the motor 302 and to cause the motor 302 to produce regenerative current. The control system 214 may generate such instructions as part of an automated driving algorithm (e.g., automatic cruise control), safety algorithm (e.g., traction control, stability control, automated emergency braking), or in response to inputs from a driver by way of an accelerator pedal 316 and/or brake pedal 318.

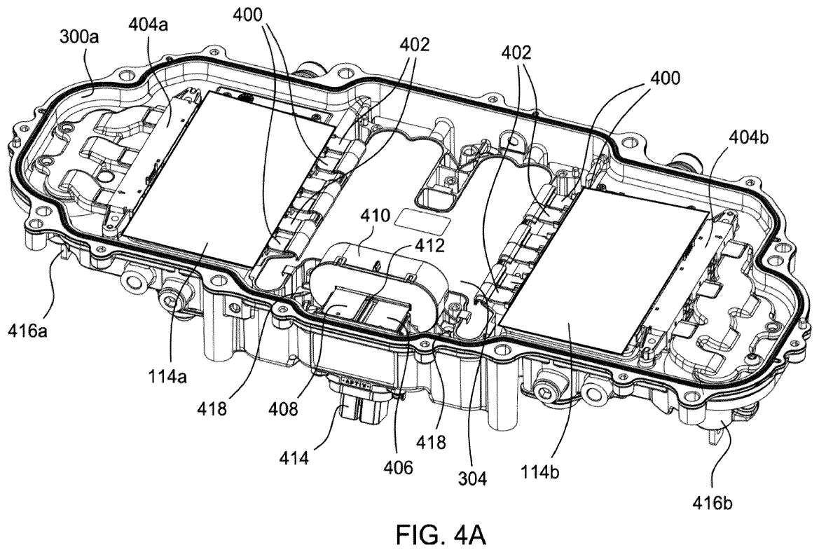

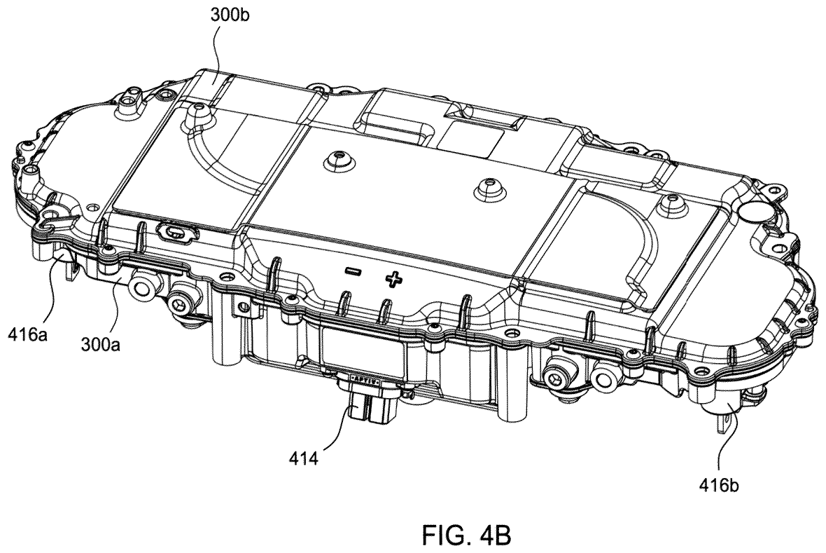

FIGS. 4A and 4B illustrate an example implementation of the traction inverter system 114, housing 300, and DC link capacitor 304. In the illustrated embodiment, the housing 300 includes a lower housing 300a and an upper housing 300b that together define a volume containing the DC link capacitor 304 and two sets of power electronics 114a, 114b. As used herein “power electronics 114a, 114b” refers to a subset of components of the traction inverter system 114 that are duplicated and used to drive separate motors 302. For example, the power electronics 114a, 114b may each include inverter switches 306 and a control module 310 (including a microprocessor 312) configured to control the inverter switches 306 as described above. In the illustrated embodiment, a single DC link capacitor 304 is coupled to both power electronics 114a, 114b. However, separate DC link capacitors 304 may also be used. With the upper housing 300b secured to the lower housing 300a, the housing 300 may be sealed from ingress of air, water, or contaminants.

The power electronics 114a, 114b each connect to one or more positive output terminals 400 and one or more negative output terminals 402 of the DC link capacitor 304. For example, in the illustrated embodiment, the DC link capacitor 304 includes three positive output terminals 400 on each side interleaved with three negative output terminals 402 on each side. The positive and negative output terminals 400, 402 may be secured to the corresponding contacts (obscured by the positive and negative output terminals 400, 402 in FIG. 4A) on the power electronics 114a, 114b by means of screws, welds, or other fastening approach.

The power electronics 114a, 114b further include output terminals 404a, 404b, respectively, that each supply AC current to a different motor 302, e.g., left and right front motors 302 of a front drive unit 112 or left and right front motors 302 of a rear drive unit 112. For example, there may be a single housing 300 and corresponding power electronics 114a, 114b for a single drive unit 112 (e.g., two-wheel drive) or two housings 300 and corresponding power electronics 114a, 114b for two drive units 112 (e.g., all-wheel drive).

The DC link capacitor 304 further includes a positive input terminal 406 and a negative input terminal 408 coupled to Batt+ and Batt−, respectively. In some embodiments, the transmission of high-frequency signals to the power electronics 114a, 114b through the DC link capacitor 304 is inhibited by a DC choke 410. The DC choke 410 may be an inductive element made of wound wires, a laminate of conductive plates (e.g., metalized plastic), or other inductive structure. The DC choke 410 may define an opening 412 for receiving the positive input terminal 406 and the negative input terminal 408 with the wires, conductive laminate, or other inductive structures forming a loop around the opening 412. When the DC choke 410 and DC link capacitor 304 are mounted to the lower housing 300, the positive input terminal 406 and the negative input terminal 408 extend outwardly from the opening 412.

The positive input terminal 406 and the negative input terminal 408 may be electrically coupled to an input connector 414. The input connector 414 may provide an interface accessible from external to the housing 300 for connecting to a cable connected to the battery 110. The positive input terminal 406 and the negative input terminal 408 may secure to an input connector 414 using welds, screws, or other fastening approach.

Output connectors 416a, 416b may be connected to the output terminals 404a, 404b of the power electronics 114a, 114b, respectively. The output connectors 416a, 416b may provide an interface accessible from external to the housing for connecting cables to the motors 302 connected to the power electronics 114a, 114b.

In the illustrated embodiment, fasteners 418 secure the DC choke 410 to the DC link capacitor 304. The fasteners 418 may additionally secure the DC link capacitor 304 to the lower housing 300a. The fasteners 418 may be embodied as screws or other type of fastener.

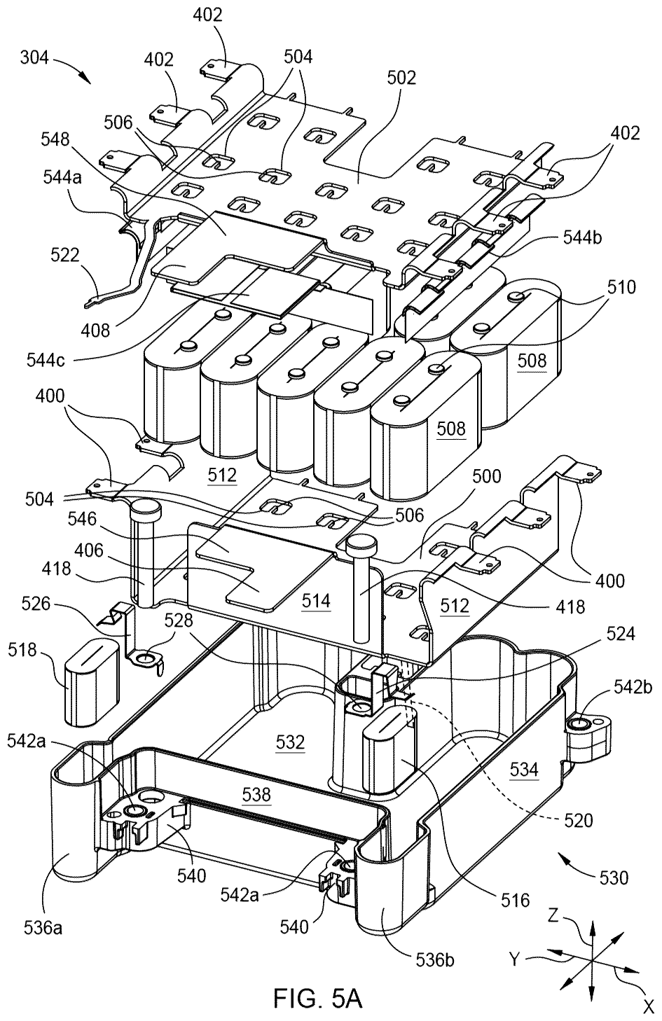

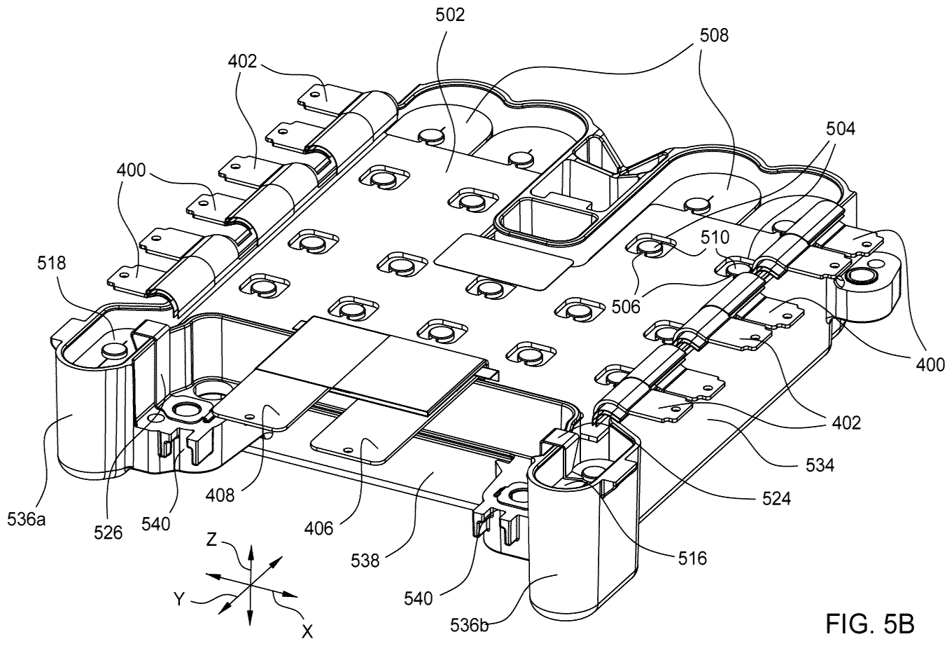

Referring to FIGS. 5A and 5B, the DC link capacitor 304 may have the illustrated configuration. The illustrated configuration may be understood with respect to X, Y, and Z directions that are mutually perpendicular. In use, the Z direction may correspond to the vertical direction (e.g., substantially parallel to the direction of gravity). However, other orientations are also acceptable. Likewise, references herein to front, back, upper, lower, upwardly, downwardly, or other positions or directions are used to facilitate understanding of the relative position and orientation of components with the understanding that the actual orientation during use may be different.

The DC link capacitor 304 may include a positive plate 500 and a negative plate 502 that are offset from one another along the Z direction and substantially (e.g., within 5 degrees of) parallel to one another and the X and Y directions. Each plate 500, 502 defines a plurality of openings 504 with a prong 506 extending into the opening 504. A plurality of capacitors 508 are positioned between the positive plate 500 and the negative plate 502. Terminals 510 of the capacitors 508 are secured to the prongs 506 on the positive and negative plates 500, 502, such as by welding or other type of fastener. The capacitors 508 are therefore connected in parallel between the positive and negative plates 500, 502.

The positive plate 500 may have sidewalls 512 extending upwardly therefrom substantially (e.g., within 5 degrees of) parallel to the Z direction. The sidewalls 512 may have the positive terminals 400 secured thereto. The sidewalls 512 may therefore function to position the positive terminals 400 substantially (e.g., within 2 mm of) aligned with the negative output terminals 402. The positive plate 500 may further have a front wall 514 secured thereto with the positive input terminal 406 secured thereto. The front wall 514 may therefore function to position the positive input terminal 406 substantially (e.g., within 2 mm of) aligned with the negative input terminals 408. In some embodiments, the positive plate 500, sidewalls 512, and front wall 514 are formed of a single piece of metal that is cut and stamped into the illustrated configuration.

The DC link capacitor may further include a positive Y capacitor 516 and a negative Y capacitor 518. The positive Y capacitor 516 provides a capacitive coupling between the positive plate 500 and a ground plane (e.g., the housing 300, which may be electrically coupled to the chassis 106 of the vehicle). The negative Y capacitor 518 provides a capacitive coupling between the negative plate 502 and the ground plane.

The positive plate 500 may define a Y contact 520 that contacts a terminal of the positive Y capacitor 516 when the DC link capacitor 304 is assembled. The negative plate 502 may define a Y contact 522 that contacts a terminal of the negative Y capacitor 518 when the DC link capacitor 304 is assembled. A positive ground connector 524 connects another terminal of the positive Y capacitor 516 to the ground plane and a negative ground connector 526 connects another terminal of the negative Y capacitor 518 to the ground plane. The fasteners 418 may pass through openings 528 in the ground connectors 524, 526 and contact the ground connectors 524, 526 to establish electrical context between the ground connectors 524, 526 and the ground plane.

The DC link capacitor 304 may be contained within a capacitor housing 530. The capacitor housing 530 may be made of plastic or other non-conductive material or may be made of metal and isolated from the DC link capacitor 304 by an insulative layer. The capacitor housing 530 may include a bottom wall 532 substantially (e.g., within 5 degrees of) parallel to the Z direction and a sidewall 534 extending around the perimeter of the bottom wall 532. The sidewall 534 extends upwardly from the bottom wall 532 substantially (e.g., within 5 degrees of) parallel to the Z direction. The sidewall 534 may be substantially parallel to the Z direction with a curved transition portion between the sidewall and the bottom wall 532. The sidewall 534 may be contoured in the X-Y plane to conform to the shape of the sidewalls 512, front wall 514, capacitors 508, and Y-capacitors 516, 518.

As is apparent in FIG. 5A, the sidewall 534 forms lobes 536a, 536b for containing the positive Y capacitor 516 and negative Y capacitor 518, respectively. The lobes 536a, 536b define a recess therebetween. For example, the lobes 536a, 536b may extend outwardly from a front portion 538 of the sidewall 534 (e.g., the portion of sidewall 534 interfacing with the front wall 514) in the Y direction. The lobes 536a, 536b may be offset from one another in the X direction to define the recess 536. The positive Y contact 520 and negative Y contact 522 may extend into the lobes 536a, 536b, respectively, to make contact with terminals of the positive Y capacitor 516 and negative Y capacitor 518, respectively.

Flanges 540 may extend into the recess 536 and define openings 542a for receiving the fasteners 418. The openings 542a may therefore be aligned with the openings 528 of the ground connectors 524, 526 during use. For example, a flange 540 may secure to the lobe 536a and the front portion 538, and a flange 540 may secure to the lobe 536b and the front portion 538. The flanges 540 may define a gap therebetween for receiving the DC choke 410. The flanges 540 may be positioned between the top and the bottom of the sidewall 534 along the Z direction, such as within 0.2 H from a midpoint of the sidewall 534 along the Z direction, where H is the height of the sidewall 534 in the Z direction. The housing 530 may define one or more additional openings 542b, such as on protrusions secured to the sidewall 534, to receive additional fasteners securing the housing 530 to the lower housing 300a.

Insulators may be positioned at various locations to prevent electrical contact and arcing between members at the electric potential of the positive plate 500 and members at the electric potential of the negative plate 502. For example, insulators 544a, 544b may be positioned between the sidewall 512 and the upper plate 500 around the positive and negative output terminals 400, 402. An insulator 544c may be positioned between the front wall 514 and the upper plate 500 around the positive and negative input terminals 406, 408.

In some embodiments, the positive input terminal 406 extends from an extension 546 formed on the positive plate 500, and the negative input terminal 408 extends from an extension 548 formed on the negative plate 502. The extensions 546, 548 may be substantially (e.g., within 5 degrees of) parallel to the X and Y directions and one another. The extensions 546, 548 may extend outwardly from the front portion 538 of the sidewall 534 along the Z direction. The extensions 546, 548 may be coextensive with one another (e.g., neither extending outwardly from the other by more than 1 mm). In the illustrated embodiment, the positive input terminal 406 is offset from the negative input terminal 408 along the X direction without overlap along the X direction. The insulator 544c, or some other insulator, may extend between the extensions 546, 548. The extensions 546, 548 may also be positioned within the DC choke 410 when the DC link capacitor 304 is assembled. The coextension of the extensions 546, 548 may facilitate canceling of differential mode noise with common mode noise being canceled by the DC choke 410.

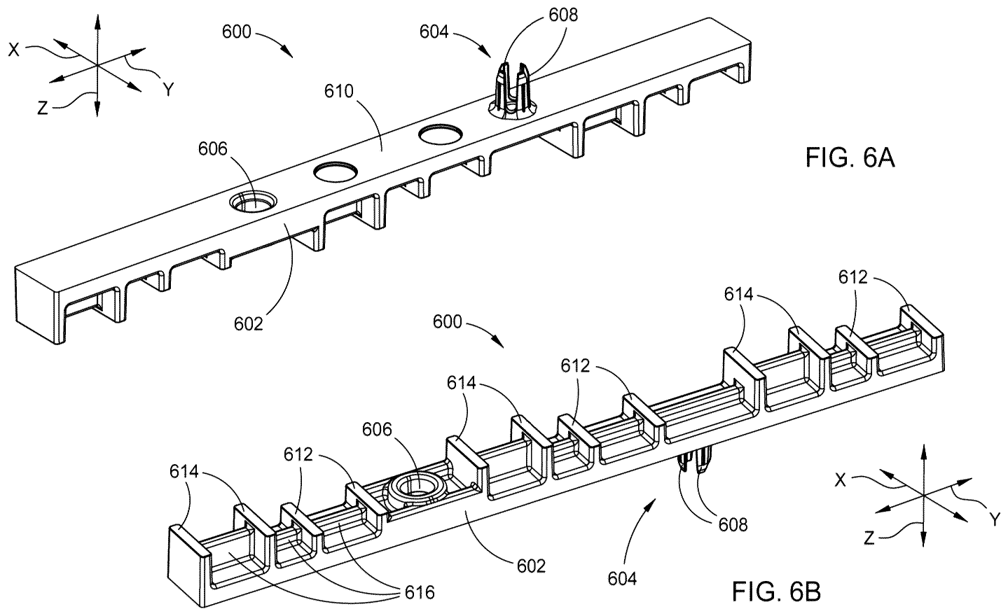

Referring to FIGS. 6A to 10, the one or more positive output terminals 400 and one or more negative output terminals 402 of the DC link capacitor 304 may be secured to contacts of the power electronics 114a, 114b by means of laser welding, spot welding, screws, or other fastening approach. Some fastening processes include applying force to the terminals 400, 402 and contacts of the power electronics 114a, 114b.

Referring specifically to FIGS. 6A and 6B, in some embodiments, a terminal block 600 is used to support the terminals 400, 402 and contacts of the power electronics 114a, 114b during a connecting process, such as laser or spot welding, placing a fastener, or other connecting approach. The terminal block 600 performs a temporary function during assembly and thereafter may not be required to continue to support the terminals 400, 402 and contacts of the power electronics 114a, 114b. Likewise, once the DC link capacitor 304 is secured to the lower housing 300a and the positive and negative output terminals 400, 402 are secured to the contacts of the power electronics 114a, 114b, the terminal block 600 is no longer removable. Accordingly, the terminal block 600 may include features to temporarily secure the terminal block 600 to the lower housing 300a. The features may advantageously engage easily without the use of additional fasteners or fastening tools in order to reduce the cost and complexity resulting from use of the terminal block 600 (gripping and placing tools may still advantageously be used). The terminal block 600 may be formed of a plastic (such as nylon, polyvinyl chloride (PVC), acrylonitrile butadiene styrene (ABS), or other polymer), composite (such as carbon fiber composite, fiberglass composite, Kevlar composite), or other non-conductive material. The terminal block 600 may include an internal metal (such as aluminum or steel) component covered with an insulator to prevent the passage of electrical current through the terminal block 600.

In the illustrated embodiment, the terminal block 600 includes a block body 602, which may have a cuboid shape with features formed thereon or therein. In particular, the block body 602 may have a cuboid shape with rounded corners, text, manufacturing markings (e.g., flashing from molding), or other features formed thereon. In use, the block body 602 has a length (L) in the Y direction that is greater than width (W) in the X direction. The width W may be greater than a height (H) in the Z direction. For example, L may be between 15 and 20 times W, and W may be between 2 and 4 times H.

The terminal block 600 has one or both of a retention feature 604 and an alignment feature 606 secured thereto or formed thereon. The retention feature 604 and/or alignment feature 606 may facilitate maintaining a position of the terminal block 600 relative to the lower housing 300a prior to placement of the power electronics 114a, 114b and DC link capacitor 304. The retention feature 604 and/or alignment feature 606 engage easily without the use of tools or additional fasteners (gripping and placement tools may still be used).

In the illustrated embodiment, the retention feature 604 is embodied as one or more biasing fingers 608, such as two, three, four, or more biasing fingers 608. The biasing fingers 608 may be deformed inwardly toward one another and thereafter recoil outwardly to retain the terminal block 600. The biasing fingers 608 may be spaced apart from one another to facilitate inward displacement. The biasing fingers 608 may be formed monolithically with the terminal block 600 such that inherent elasticity of the biasing fingers 608 provides the outward recoil of the biasing fingers 608. Outwardly facing surfaces of the biasing fingers may be beveled, sloped, or otherwise contoured to facilitate insertion. In the illustrated embodiment, outward facing surfaces are smooth. However, barbs or other structures may also be formed thereon to further resist removal.

The alignment feature 606 may cooperate with the retention feature 604 to align the terminal block 600 in the X, Y plane, such as substantially (e.g., within 5 degrees of) parallel to the Y direction when installed on the lower housing. The alignment feature 606 may function to only to align the terminal block or may additionally retain the terminal block 600 relative to the lower housing 300a. For example, the alignment feature 606 may be another set of biasing fingers 608.

In the illustrated embodiment, the alignment feature 606 is an opening defined in the block body 602. The opening may extend through the same surface 610 of the block body from which the alignment feature 606, e.g., the surface 610 that is placed in contact with the lower housing 300a during use. The surface 610 may be flat within manufacturing tolerances with the retention feature 604 projecting outwardly therefrom. The opening may extend completely through the block body 602 as in the illustrated embodiment or only partially, e.g., a depth of from 0.1 H and 0.5 H.

The retention feature 604 and alignment feature 606 may be offset from one another, such as between 0.25 L and 0.75 L. The retention feature 604 and alignment feature 606 may be offset inwardly from ends of the block body 602, such as between 0.1 L and 0.25 L.

Referring to FIG. 6B, the terminal block 600 may include one or more features formed on the block body 602 opposite the surface 610. However, in other embodiments, the surface opposite the surface 610 is likewise flat. In the illustrated embodiment, a plurality of contact alignment fins 612 may be formed on the terminal block 600 and distributed along the Y direction. Contacts of the power electronics 114a, 114b and/or the positive and negative output terminals 400, 402 may seat between pairs of alignment fins 612.

In some embodiments, additional support fins 614 extend outwardly from the block body 602 and are distributed along the Y direction among the contact alignment fins 612. The support fins 614 may extend outwardly farther in the Z direction than the contact alignment fins 612, such as by at least 1, 4, or 8 millimeters. The support fins 614 may contact the upper housing 300b when installed and support the upper housing 300b. The support fins 614 may be arranged in pairs as shown. The contact alignment fins 612 may be arranged in pairs adjacent to a support fin 614 such that, for each pair of contact alignment fins 612, regions are defined both of (a) between the pair of contact alignment fins 612 and (b) between one of the pair of contact alignment fins 612 and one of the support fins 614.

In some embodiments, ribs 616 may extend in the Y direction between adjacent fins 612, 614. The ribs 616 may be a result of manufacturing constraints of an injection molding process. The ribs 616 may further stiffen the terminal block 600 and support contacts of the power electronics 114a, 114b during a fastening step.

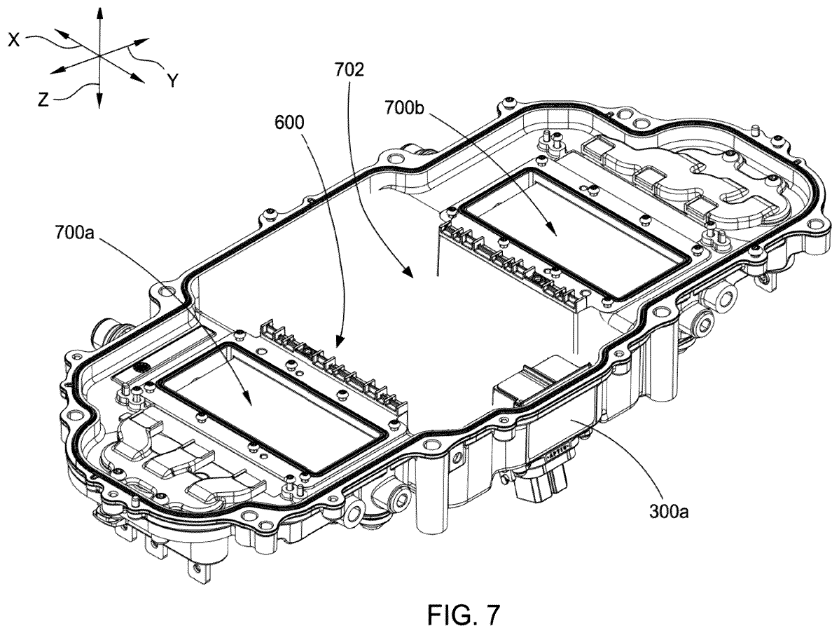

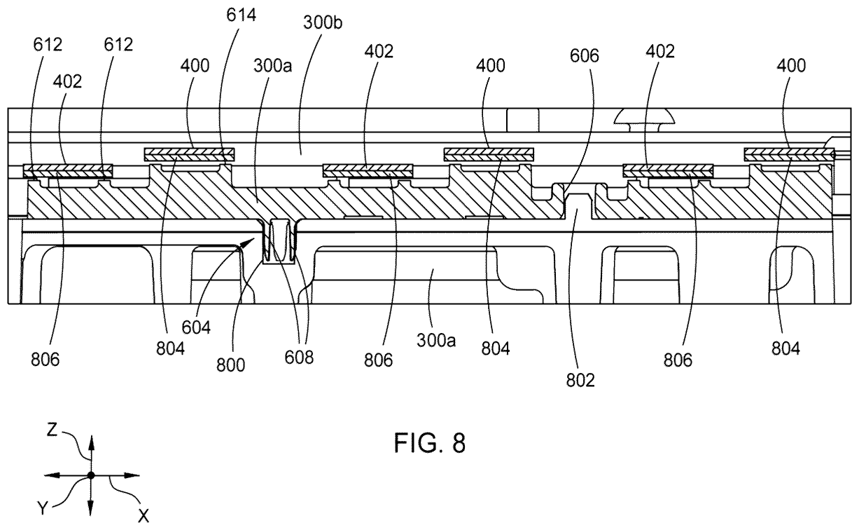

FIGS. 7 and 8 illustrate one method of use of the terminal block 600. The lower housing 300a may define bays 700a, 700b for receiving the power electronics 114a, 114b, respectively, and a bay 702 for receiving the DC link capacitor. Terminal blocks 600 may be placed between the bay 702 and the bay 700a and between the bay 702 and the bay 700b.

Referring specifically to FIG. 8, the lower housing 300a may define an opening 800 for receiving the retention feature 604 and a protrusion 802 for inserting within the alignment feature 606. The opening 800 may have a flared entrance to facilitate insertion of the retention feature 604. The inner diameter of the opening 800 (e.g., in the X-Y plane) may be smaller than a circle containing the undeformed retention feature 604 such that deformation of the retention feature 604 is required to insert the retention feature 604 in the opening 800. For example, the biasing fingers 608 may splay outwardly to a greater extent than the opening 800 such that deformation of the biasing fingers 608 is required to insert the biasing fingers 608 in the opening 800.

The retention force achieved by the retention feature 604 may be sufficient to resist unintentional displacement of terminal block 600 from the lower housing 300a. For example, the retention feature 604 may grip the opening 800 sufficient to resist a removal force (e.g., directed parallel to the central axis of the opening 800) of at least 2, 3, 4, or 5 times the weight of the terminal block 600. The opening 800 may be smooth within the limits of the manufacturing process used to form the opening 800 (e.g., drill bit) or may be textured to promote gripping. The opening 800 may include barbs, undercut features, or other features to engage with the retention feature 604 and resist removal.

The protrusion 802 may insert within the alignment feature 606 when the retention feature 604 is inserted within the opening 800 and resist rotation in the X-Y plane, e.g., about an axis parallel to the Z direction. The protrusion 802 may slide freely within the alignment feature 606 or may have an interference fit requiring some force to insert and thereafter providing resistance to removal in addition to the grip of the retention feature 604 within the opening 800.

With the terminal blocks 600 in place as shown in FIG. 7, power electronics 114a, 114b may be installed in the bays 700a, 700b, and the DC link capacitor 304 may be installed within the bay 702. The positive contacts 804 and negative contacts 806 of power electronics 114a, 114b may be placed between adjacent contact alignment fins 612 or between an alignment fin 612 and an adjacent support fin 614. The positive and negative output terminals 400, 402 are then placed over the positive and negative contacts 804, 806, respectively, as shown in FIG. 8. The contacts 804, 806 may rest on ribs 616 in this configuration or may be pressed against the ribs 616 only during a fastening step that fastens the positive and negative output terminals 400, 402 to the positive and negative contacts 804, 806. The engagement of the contacts 804, 806 with the ribs 616 may facilitate maintaining the positions of the contacts 804, 806 with the positive and negative output terminals 400, 402 overlapping the contacts 804, 806 during the fastening step.

In the illustrated embodiment, the positive and negative contacts 804, 806 are positioned between the lower housing 300a and the positive and negative output terminals 400, 402 such that the power electronics 114a, 114b are installed before the DC link capacitor 304. However, the opposite configuration and order of assembly may also be performed.

The upper housing 300b may be secured to the lower housing 300a following installation of the power electronics 114a, 114b and DC link capacitor 304 and fastening of the positive and negative output terminals 400, 402 to the positive and negative contacts 804, 806, respectively.

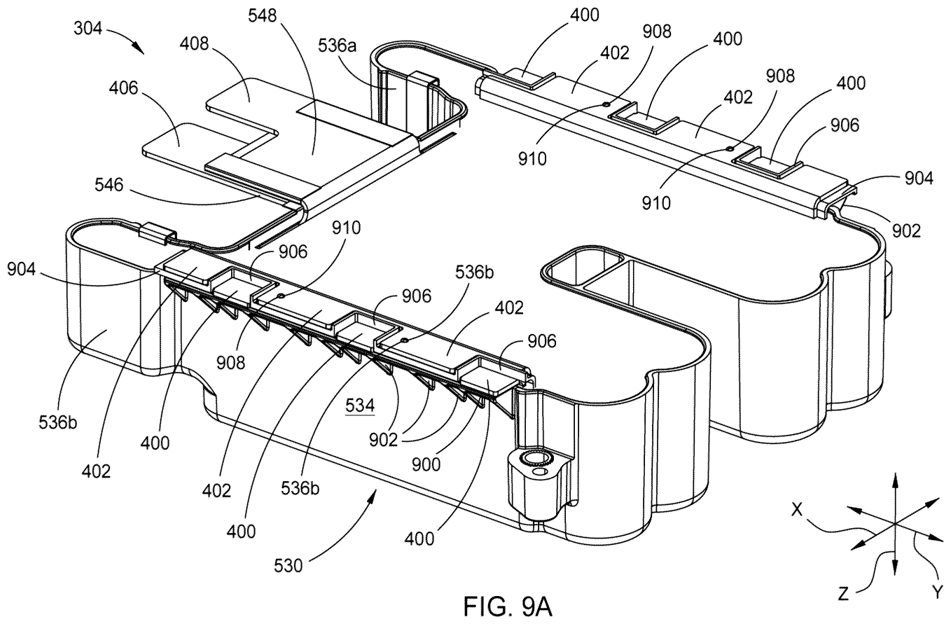

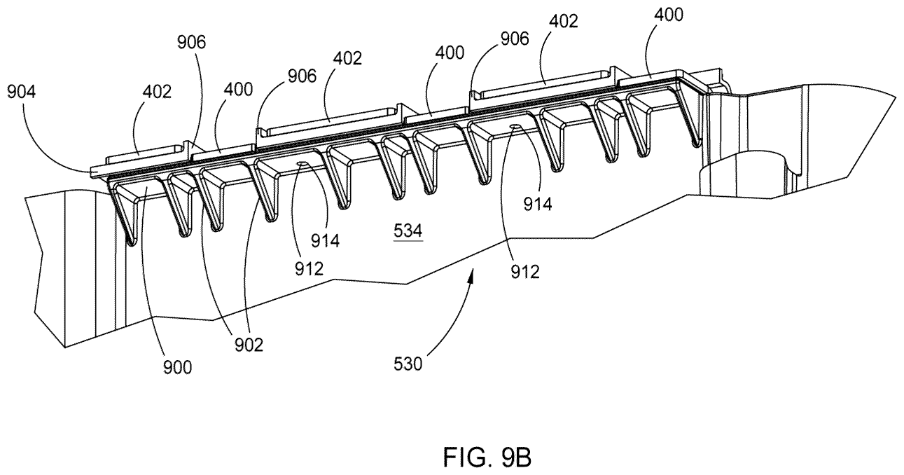

Referring to FIGS. 9A and 9B, in some embodiments, terminal blocks 900 may be secured directly to the capacitor housing 530 of the DC link capacitor 304, such as by being formed monolithically with the capacitor housing 530. For example, the terminal blocks 900 may be formed by co-molding with the capacitor housing 530. The terminal blocks 900 may be implemented as a flange extending outwardly in the X direction from the sidewall 534. The terminal blocks 900 may extend outwardly in the X direction to within at least 3, 2, or 1 millimeters of the distal ends of the positive and negative output terminals 400, 402. In some embodiments, the terminal blocks 900 extending slightly (e.g., between 0.1 and 2 millimeters) outwardly in the X direction from the distal ends of the positive and negative output terminals 400, 402. In the illustrated embodiments, the terminal blocks 900 are substantially (e.g., within 1 mm of) flush with the top edge of the sidewall 534 along the Z direction.

The terminal blocks 900 resist force exerted on the positive and negative output terminals 400, 402 and the positive and negative contacts 804, 806 during a fastening operation. The terminal blocks 900 may therefore be supported by ribs 902 distributed along the Y direction at regular intervals or the illustrated irregular intervals. The distribution of the ribs 902 may correspond to expected distribution of force on the terminal blocks. The ribs 902 may have the illustrated triangular shape spanning between the terminal blocks 900 and the sidewall 534.

Insulators 904 may be positioned between the terminal blocks 900 and some or all of the positive and negative output terminals 400, 402. In the illustrated embodiment, an insulator 904 is positioned between each terminal block 900 and the negative output terminals 402 supported by that terminal block 900. Each insulator 904 may further include one or more ridges 906. The ridges 906 may be interposed between the negative output terminals 402 and the positive output terminals 400 to facilitate alignment and prevent contact and arcing between the positive and negative output terminals 400, 402.

The insulators 904 may be formed of a molded plastic and may include one or more features to facilitate alignment with respect to the terminal blocks 900 and one or both of the positive and negative output terminals 400, 402. For example, each insulator 904 may define one or more protrusion 908 that inserts within one or more openings 910 defined by one of the positive or negative output terminals 400, 402, such as the illustrated negative output terminals 402.

Referring specifically to FIG. 9B, in some embodiments, each insulator 904 may further define one or more protrusions 912 on an opposite side of the insulator 904 from the protrusion 908. Each protrusion 912 may insert within an opening 914 defined by the terminal block 900 supporting the insulator 904.

In use, the DC link capacitor 304 and corresponding housing 530 with terminal blocks 900 is placed in bay 702 followed by placing the power electronics 114a, 114b in bays 700a, 700b. The positive and negative contacts 804, 806 of the power electronics 114a, 114b are then fastened to the positive and negative output terminals 400, 402 of the DC link capacitor 304 with the terminal blocks supporting the positive and negative contacts 804, 806 and the positive and negative output terminals 400, 402 during the fastening process. The upper housing 300b may then be mounted to the lower housing 300a.

The descriptions of the various embodiments of the present disclosure have been presented for purposes of illustration. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure may exceed the specific described embodiments. Instead, any combination of the features and elements, whether related to different embodiments, is contemplated to implement and practice contemplated embodiments.

Furthermore, although embodiments disclosed herein may achieve advantages over other possible solutions or over the prior art, the embodiments may achieve some advantages or no particular advantage. Thus, the aspects, features, embodiments and advantages discussed herein are merely illustrative.

While the foregoing is directed to embodiments of the present disclosure, other and further embodiments may be devised without departing from the basic scope thereof, and the scope thereof is determined by the claims that follow.

What is claimed is:

1. A capacitor assembly, comprising:
a traction inverter system housing;
a set of power electronics defining two or more contacts, the set of power electronics mounted within the traction inverter system housing;
a capacitor housing containing a capacitor mounted within the traction inverter system housing, the capacitor comprising two or more terminals extending outwardly therefrom; and
a terminal block configured to maintain a position of the two or more terminals wherein the two or more terminals are overlapping the two or more contacts before the two or more terminals are attached to the two or more contacts.

2. The capacitor assembly of claim 1, wherein the terminal block is secured to the capacitor housing.

3. The capacitor assembly of claim 2, wherein the terminal block is co-molded with the capacitor housing.

4. The capacitor assembly of claim 3, wherein the terminal block comprises a flange extending outwardly from a sidewall of the capacitor housing.

5. The capacitor assembly of claim 1, wherein the set of power electronics comprises a first set of power electronics, the terminal block is a first terminal block, the two or more terminals are two or more first terminals, and the two or more contacts are two or more first contacts, the capacitor assembly further comprising:
a second set of power electronics comprising two or more second contacts, the capacitor comprising two or more second terminals overlapping the two or more second contacts, the capacitor housing positioned between the first set of power electronics and the second set of power electronics; and
a second terminal block secured to the capacitor housing independently of attachment of the two or more second contacts to the two or more second terminals, the second terminal block configured to support the two or more second terminals during a fastening operation attaching the two or more second terminals to the two or more second contacts.

6. The capacitor assembly of claim 1, wherein the set of power electronics are configured to convert direct current to alternating current.

7. A capacitor assembly, comprising:
a traction inverter system housing;
a set of power electronics defining two or more contacts, the set of power electronics mounted within the traction inverter system housing;
a capacitor housing containing a capacitor mounted within the traction inverter system housing, the capacitor comprising two or more terminals extending outwardly therefrom and overlapping the two or more contacts; and
a terminal block configured to maintain a position of the two or more terminals wherein the two or more terminals are overlapping the two or more contacts before the two or more terminals are attached to the two or more contacts, the terminal block comprising a retention feature configured to secure the terminal block to the traction inverter system housing.

8. The capacitor assembly of claim 7, wherein the retention feature is configured to secure to the traction inverter system housing without use of additional fasteners.

9. The capacitor assembly of claim 8, wherein the terminal block comprises a plurality of biased fingers configured to insert within a retention opening defined by the traction inverter system housing and press outwardly against the retention opening to resist removal of the terminal block from the retention opening.

10. The capacitor assembly of claim 9, wherein the plurality of biased fingers are configured to withstand removal from the retention opening up to a removal force of at least two times a weight of the terminal block.

11. The capacitor assembly of claim 7, wherein the traction inverter system housing defines a first anti-rotation feature offset from the retention feature, and the terminal block defines a second anti-rotation feature configured to engage the first anti-rotation feature to resist rotation of the terminal block relative to the traction inverter system housing.

12. The capacitor assembly of claim 11, wherein the first anti-rotation feature is a protrusion, and the second anti-rotation feature is an opening configured to receive the protrusion.

13. A method comprising:
mounting a set of power electronics within a traction inverter system housing, the set of power electronics including two or more contacts;
mounting a capacitor housing containing a capacitor within the traction inverter system housing using fasteners, the capacitor comprising two or more terminals extending outwardly therefrom and overlapping the two or more contacts, the two or more terminals and the two or more contacts extending over a terminal block secured to the capacitor housing or the traction inverter system housing without fasteners; and
attaching the two or more terminals to the two or more contacts while supporting the two or more terminals using the terminal block.

14. The method of claim 13, wherein the terminal block is co-molded with the capacitor housing.

15. The method of claim 13, further comprising engaging a retention feature formed on the terminal block with the traction inverter system housing without use of additional fasteners.

16. The method of claim 15, wherein the retention feature comprises a plurality of biased fingers, the method further comprises deflecting the plurality of biased fingers as the plurality of biased fingers are inserted within a retention opening defined by the traction inverter system housing.

17. The method of claim 16, further comprising engaging a first anti-rotation feature defined by the traction inverter system housing with a second anti-rotation feature defined by the terminal block effective to resist rotation of the terminal block relative to the traction inverter system housing.

18. The method of claim 17, wherein the first anti-rotation feature is a protrusion, and the second anti-rotation feature is an anti-rotation opening, the method further comprising inserting the protrusion within the anti-rotation opening.

19. The method of claim 13, wherein the set of power electronics comprises a first set of power electronics, the terminal block is a first terminal block, the two or more terminals are two or more first terminals, and the two or more contacts are two or more first contacts, the method further comprising:
mounting a second set of power electronics within a traction inverter system housing, the second set of power electronics including two or more second contacts, the capacitor comprising two or more second terminals extending outwardly therefrom and overlapping the two or more contacts, the two or more second terminals and the two or more second contacts extending over a second terminal block secured to the capacitor housing or the traction inverter system housing without fasteners; and
attaching the two or more second terminals to the two or more second contacts while supporting the two or more second terminals using the second terminal block.

20. The method of claim 13, wherein the set of power electronics is configured to convert direct current to alternating current.
